(19) United States
(12) Patent Application Publication
(10) Pub. No.: US 2004/0241557 A1
(43) Pub. Date: Dec. 2, 2004

(54) Mask, mask blank, photosensitive material therefor and fabrication thereof

(76) Inventors: Robert A. Bellman, Painted Post, NY (US); Nicholas F. Borrelli, Elmira, NY (US); George B. Hares, Corning, NY (US); Charlene M. Smith, Corning, NY (US); Robin M. Walton, Painted Post, NY (US)

Correspondence Address: CORNING INCORPORATED, SP-TI-3-1, CORNING, NY, 14831

(21) Appl. No.: 10/448,682

(22) Filed: May 29, 2003

(51) Int. Cl. B32B 9/00; C03C 15/00; G03F 9/00; C03B 18/00; B32B 17/06

(52) U.S. Cl. 430/5; 428/428; 65/404; 65/30.1

(57) ABSTRACT

Disclosed are masks and mask blanks for photolithographic processes, photosensitive materials and fabrication method therefor. Photosensitive materials are used in the masks for recording permanent pattern features via UV exposure. The masks are advantageously phase-shifting, but can be gray-scale masks having index patterns with arbitrary distribution of refractive index and pattern dimension. The masks may have features above the surface formed from opaque or attenuating materials. Alumino-boro-germano-silicate glasses having a composition comprising, in terms of mole percentage, 1-6% of Al₂O₃, 10-36% of B₂O₃, 2-20% of GeO₂, 40-80% of SiO₂, 2-10% of R₂O, where R is selected from Li, Na and K, and expressed in terms of weight percentage of the glass, 0-5% of F, can be used for the mask substrate.

### FIELD OF THE INVENTION

The present invention relates to mask and mask blank, photosensitive material therefor and fabrication thereof. In particular, the present invention relates to UV (ultraviolet) photosensitive materials, photolithographic mask and mask blank comprising such materials and fabrication method therefor. The present invention is useful, for example, in the fabrication of phase-shifting photomasks and grayscale photomasks.

### BACKGROUND OF THE INVENTION

Photolithography is the process used by semiconductor chip manufacturers to transfer integrated circuit patterns through a mask onto a silicon wafer. An exemplary traditional binary mask is a fused quartz plate, with an opaque Cr film on it. Openings in the mask, corresponding to the IC features, allow light from an optical projection system (called a stepper because the exposure is a step and repeat process) to irradiate a photosensitive polymer (photoresist) layer coated on the silicon wafer. After resist development, or its selective removal (positive resist) in the pattern of the circuit design, the silicon is now exposed to allow etching, metal deposition, ion implantation or other processing, followed by removal or “stripping” of the photoresist. To make a modem, complex microprocessor or memory chip requires as many as 20 iterations of this process with different but complementary (and critically aligned) masks (or mask set). One limitation of photolithography is that there is a minimum feature size that can be imaged on the wafer, determined by the optics of the stepper, the wavelength of the imaging light, and the particular process ( e.g., contrast of the photoresist material). As the minimum feature size is reduced, speed and density in chips increase as does the cost of the photolithography tool substantially. Fortunately, a number of strategies have been developed to extend the usefulness of any optical lithography generation. One of these optical extensions is the phase-shifting mask (PSM). It can enhance resolution beyond the wavelength-imposed diffraction limit. Since some fraction of the light used in lithography is coherent, phase-shifting masks work by destructive optical interference to enhance imaging contrast.

The resolution of an image formed by a projection stepper in a photolithography system is defined by the following equation:

R=k₁·(λ/NA) (1)

wherein R is resolution, k₁ is process-dependent constant, λ is the illumination wavelength, and NA=sinθ is numerical aperture of the projection lens. Depth of focus (DoF) is another important parameter of a photolithography process besides resolution R. Usually a large DoF is desired, because a larger DoF renders the process more tolerant to departure in wafer flatness and photoresist thickness uniformity. DoF is determined according to the following equation:

DoF=k₂·(λ/NA²) (2)

where k₂ is another process-dependent constant.

From these above equations (1) and (2), it can be seen that, in order to enhance resolution R, the following approaches may be employed (i) using a shorter illumination wavelength λ; (ii) using a projection system having larger numerical aperture NA; or (iii) lower constant k₁ by improving the process such as by using photo-shifting mask or a higher contrast photoresist.

Phase-shifting masks can improve resolution without sacrificing DoF. Since optical interference does not depend critically upon a perfectly focused image, phase-shift masks can actually increase DoF in comparison to traditional Cr masks. Two types of phase-shifting masks are commonly used in lithography: alternating aperture phase-shifting masks and the embedded attenuating phase-shifting mask. FIG. 1 compares the imaging process for a traditional Cr binary mask and a simple form of the alternating aperture phase-shifting mask. Each mask has two closely spaced openings. Because the imaging light is an electromagnetic wave, it has both an electric field amplitude and a phase; the radiance or dose needed to expose the photoresist is proportional to the square of this amplitude. When light passes through adjacent apertures in the Cr mask, the amplitude profiles broaden due to diffraction and spatial filtering of the optical system. At the wafer, the electric field amplitude overlap and interfere constructively because the light is at least partially coherent. At the wafer, the intensity of the light, which is proportional to the total amplitude squared, is large everywhere and the resist will also be exposed between the apertures, blurring the separate features together. In the simple phase-shift mask, light that traverses one of the apertures is phase-shifted 180°. Again the electric field amplitudes of light passing through the two apertures broaden, but because one component is phase-shifted 180°, they interfere destructively, such that the net amplitude of the imaging light becomes zero (or dark) between adjacent apertures or features. The light intensity passing through the separate apertures is now resolved at the wafer and therefore resolution of imaged features is enhanced.

The alternating aperture phase-shifting mask is particularly well suited for printing closely spaced lines. Typically, it provides a 50% improvement in resolution compared to traditional binary Cr masks. In a conventional practical mask design, the quartz substrate is etched to produce the 180° phase-shift masks, especially when the features to be printed are in complicated circuit patterns. An unwanted result is that the abrupt transition between 0° and 180° always prints as a dark line, and it can bridge or short circuit isolated lines in some circuit designs. Although there are strategies to circumvent this, implementing them adds complexity to the mask design, especially for intricate circuits.

FIGS. 2A, 2B and 2C shows plan, side elevation (along line A) and end elevation (along line B) views of the result of steps in construction of an alternating aperture PSM as currently implemented commercially. A substrate 10 is made of a material such as a fused quartz plate or other stable material which must be transparent to the light used in the photolithography for a transmission mask. The substrate 10 coated with an opaque (“chrome”) film 12 in which openings 14 and 16 have been opened by normal photoresist application, exposure and development, followed by chrome etch to form a conventional chrome-on-glass (COG) photomask. After stripping the original photoresist, the photomask is then recoated with a resist film and apertures are opened in the resist film at the locations of apertures which will be phase-shifted. The openings in this second resist film are larger than those in the underlying chrome to accommodate possible mis-registration. The photomask is then etched and the chrome 12 exposed in the resist openings is used as a mask to etch the underlying substrate 10 to a depth below the original surface to make the depressions after the etching of the substrate 10. The depth of the features etched in the substrate 10 is carefully chosen on the basis of the wavelength of the light to be used in the photolithography and the difference in the index of refraction of the material of the substrate and the ambient atmosphere in which the phase-shifting mask is used.

The other type of phase-shifting mask is the embedded attenuating phase-shifting mask (EAPSM). It is schematically illustrated in FIG. 3A. This mask allows some (typically 6-18%) of the imaging illumination, phase-shifted 180°, to be transmitted by the mask in the normally opaque areas of a corresponding Cr binary mask. In this case, the diffraction of light that passes through an opening in the mask. Again, even though the out of phase electric field amplitude is only a fraction of the non-shifted light amplitude passing though the aperture, their profiles interfere destructively (net amplitude is zero between apertures) and sharper contrast and improvement in DoF is achieved in imaging. While attenuating phase-shift masks do not afford as much resolution enhancement as the fully transparent alternating aperture masks, they can be fabricated to work for complex circuit patterns using conventional mask making techniques, making them attractive for replacement of Cr binary masks when printing features with sub-wavelength resolution. EAPSMs are particularly suited for printing contacts and isolated clear circuit features with special off-axis illumination. The production of the EAPSMs involves multiple steps of resist deposition, exposure, development, stripping, as well as deposition and etching of Cr and phase shift thin films. FIG. 3B illustrates schematically the steps for producing a typical EAPSM using TiSiN as the attenuating phase-shifting material.

Chromeless phase-shifting mask has been developed recently in chromeless phase lithography (CPL). CPL uses chromeless features on the masks to define patterns that have nearly 100% transmission and are phase shifted by 180°. FIG. 4 is a schematic illustration of how a chromeless mask functions. The phase shift is created by etching the quartz substrate of the mask to a depth that is dependent on the wavelength of the imaging system. Using the etched quartz to induce a phase shift, it is possible to build the desired 100% transmission phase structures for any given wavelength using standard chrome on quartz substrates. CPL of this type usually requires a higher NA and a strong off-axis illumination in order to form the high contrast aerial images.

In the production of all of the prior art phase-shifting masks, very complex multi-step resist deposition, exposure, development and stripping are required. And the resulted phase-shifting mask has an uneven surface even when no Cr layer is applied. This is because the phase shift effect is caused by an additional thin film having a differing refractive index than the substrate or by varying thickness of the substrate. In the prior art phase-shifting masks, in order to obtain a 180° phase shift, the following requirement must be met:

d·(nₛ−1)≈λ/2 (3)

where d is the thickness of the phase shift film deposited on top of the substrate, or the height of the phase shift steps in a chromeless phase-shifting mask, nₛ is the refractive index of the phase shift film or the substrate in a chromeless phase-shifting mask, and λ is the illumination wavelength.

The phase shifting approach offers great resolution improvement with 25 nm gate length silicon-on-insulator (SOI) devices using a 248-nm stepper. This method has a deep subwavelength potential. SOI transistors with polysilicon gate lengths of 90, 25 and 9 nm have been demonstrated manufacturable by this approach using a 248-nm stepper. However, for the reasons mentioned above, this approach has so far suffered from impediments such as high mask cost, long turnaround time and difficult inspectability/repair.

Therefore, there remains a genuine need of a phase-shifting mask that overcomes the drawbacks of the current phase-shifting masks described above.

### SUMMARY OF THE INVENTION

The present inventors have discovered a photosensitive material, which, upon exposure to certain radiation, has an induced refractive index change. The material can be used in the production of phase shift photomasks. By selectively exposing a plate made of such photosensitive material to radiation, patterns of material having differing refractive index than that of the original plate can be created within the plate. A near 180° phase shift can be effected if the following condition is met:

d·(n₁−n₀)≈λ/2 (4)

where d is the effective thickness of the exposed area with an induced refractive index, n₁ is the refractive index of the material with induced refractive index change after exposure, and n₀ is the refractive index of the material without induced refractive index change. Because of the photosensitive property, this material can be used in photomasks in the field of microlithography for the manufacture of integrated circuits, magnetic devices and other micro-devices such as micro-machines. Manufacture of masks, especially phase-shifting masks based on substrates made of these photosensitive materials is less complex than conventional phase-shifting masks.

Accordingly, a first aspect of the present invention is a mask for use in microlithography for the manufacture of integrated circuits, magnetic devices, and other micro-devices such as micro-machines. The mask of the present invention has a pattern P₀ transferable onto an image-receiving substrate when subjected to illumination radiation in a lithographic process, comprises a UV photosensitive substrate S₁ consisting of (i) a UV induced index pattern P₁ and (ii) parts P₂ that are not UV induced, wherein the index pattern P₁ has a refractive index no at the wavelength of the illumination radiation, the non-UV induced parts P₂ has a refractive index n₀ at the wavelength of the illumination radiation, with n₀≠n₁, and n₀ and n₁ remain substantially unchanged when the mask is exposed to the illumination radiation during the lithographic process.

In a preferred embodiment, in the mask of the present invention, n₁−n₀>1×10⁻⁴. In another preferred embodiment, in the mask of the present invention, the index pattern P₁ has a thickness d chosen to create a near 180° phase shift of the illumination radiation used in the lithographic process, with respect to the non-UV induced parts P₂. The edge of the index pattern may have a refractive index or thickness gradient. In still another preferred embodiment, the index pattern has an arbitrarily modulated dimension in terms of thickness, width and length. In one embodiment, the index pattern is a grating having a pitch of less than 300 nm. In one embodiment, above the surface of the substrate S₁ of the mask of the present invention, there exist additional feature patterns P₃ formed by materials opaque or attenuating to the illumination radiation used in the lithographic process. Such opaque material may be, for example, Cr or modified Cr. And the attenuating material may create 180° phase shift with respect to the ambient atmosphere in which the mask is placed during the lithographic process.

In a preferred embodiment, in the mask of the present invention, the substrate S₁ is formed by UV photosensitive alumino-boro-germano-silicate glass having a composition comprising, expressed in terms of mole percentage, 1-6% of Al₂O₃, 10-36% of B₂O₃, 2-20% of GeO₂, 40-80% of SiO₂, 2-10% of R₂O, where R is selected from Li, Na and K, and expressed in terms of weight percentage of the glass, 0-5% of F. Preferably, the glass has a composition comprising, expressed in terms of mole percentage, 2-6% of Al₂O₃, 20-30% of B₂O₃, 5-20% of GeO₂, 42-67% of SiO₂, 2-6% of R₂O, where R is selected from Li, Na and K, and expressed in terms of weight percentage of the glass, 0-5% of F. Preferably, the glass is further loaded with H₂ molecules at a level of at least 10¹⁸ molecules/cm³.

A second aspect of the present invention is a process for making a mask having a pattern P₀ transferable onto an image-receiving substrate when subjected to illumination radiation in a lithographic process, comprising the following steps:

(a) providing a UV photosensitive substrate S₀ having a refractive index no at the wavelength of the illumination radiation to which the mask is subjected to during the lithographic process;

(b) selectively exposing part of the surface of the substrate S₀ to UV radiation of less than 280 nm with an effective fluence for an effective amount of time, whereby producing a substrate S₁ consisting of (i) a UV induced index pattern P₁ having a modulated refractive index n₁, with n₁≠n₀, and (ii) parts P₂ that are not UV induced having a refractive index n₀; and

(c) optionally, forming pattern features P₃ on a surface of the substrate S₀ or S₁ by depositing films of materials opaque or attenuating to the illumination radiation.

In a preferred embodiment of the process of the present invention, in step (b), the fluence and wavelength of the UV radiation used to pattern the substrate S₀, as well as the exposure time are chosen such that the effective thickness d and the refractive index n₁ of the index pattern P₁ meet the following requirement:

d·(n₁−n₀)≈λ/2 (4)

where λ is the wavelength of the illumination radiation used in the lithographic process, thereby the pattern P₁ creates a near 180° phase shift of the illumination radiation with respect to the non-UV induced parts P₂.

In one embodiment of the process of the present invention, in step (b), the fluence and wavelength of the UV radiation used to pattern the substrate S₀, as well as the exposure time are chosen such that the index pattern P₁ has a tapering edge in terms of amount of phase shift. The fluence of the UV radiation for patterning the substrate S₀ may be adjusted by tuning the fluence of the radiation source or by using gradient attenuating mask. In one embodiment, a contact phase mask is used in patterning the substrate S₀.

In an embodiment of the process of the present invention, in step (c), additional features P₃ are formed on one surface of the substrate S₁ or S₀. Step (c) may be carried out before or after step (b). Preferably, such additional features are formed on the substrate surface to which the UV patterning radiation has been or is to be directly applied in step (b). The additional features in step (c) may be formed by using conventional methods, including photoresist deposition, exposure, development, selective etching of the deposited material, resist stripping, etc. Additional attenuating phase-shift features may be created as part of features P₃.

In a preferred embodiment of the process of the present invention, the photosensitive substrate S₀ in step (a) is formed by an alumino-boro-germano-silicate glass having a composition comprising, expressed in terms of mole percentage, 1-6% of Al₂O₃, 10-36% of B₂O₃, 2-20% of GeO₂, 40-80% of SiO₂, 2-10% of R₂O, where R is selected from Li, Na and K, and expressed in terms of weight percentage of the glass, 0-5% of F. Preferably, the glass has a composition comprising, expressed in terms of mole percentage, 2-6% of Al₂O₃, 20-30% of B₂O₃, 5-20% of GeO₂, 42-67% of SiO₂, 2-6% of R₂O, where R is selected from Li, Na and K, and expressed in terms of weight percentage of the glass, 0-5% of F. In one embodiment, the glass is further located with H₂ molecule at a level of at least 10¹⁸ molecules/cm³. Preferably, substrate S₀ has flat surfaces.

A third aspect of the present invention is a photosensitive alumino-boro-germano-silicate glass with a refractive index no, which, upon being exposed to UV radiation less than 280 nm with a fluence of 50 mJ/cm² for 60 minutes, has a differing modulated refractive index n₁, with n₁≠n₀, said glass having a composition comprising, expressed in terms of mole percentage, 2-6% of Al₂O₃, 20-30% of B₂O₃, 5-20% of GeO₂, 42-67% of SiO₂, 2-6% of R₂O, where R is selected from Li, Na and K, and expressed in terms of weight percentage of the glass, 0-5% of F. Preferably, the glass has a composition comprising, expressed in terms of mole percentage, 2-6% of Al₂O₃, 23-27% of B₂O₃, 10-18% of GeO₂, 45-65% of SiO₂, 2-5% of R₂O, where R is selected from Li, Na and K, and expressed in terms of weight percentage of the glass, 1-4.5% of F. Preferably, the glass is further loaded with H₂ molecules at a level of at least 10¹⁸ molecules/cm³.

The final aspect of the present invention is a mask blank comprising a substrate S₀ for use in a photolithographic process, wherein:

(I) the substrate S₀ is formed by a UV photosensitive material having a refractive index n₀ at the wavelength of the radiation used in a lithographic process;

(II) upon selective exposure to UV radiation less than 280 nm at an effective fluence for an effective amount of time, an index pattern P₁ transferable to an image-receiving substrate when subjected to illumination radiation in a lithographic process can be formed within the substrate S₀, said index pattern P₁ having a refractive index n₁, with n₁≠n₀; and

(III) the substrate S₀ is not induced to have an refractive index change when exposed to the illumination radiation used in the lithographic process.

The mask blank of the present invention may further bear on a surface of the substrate S₀ a film opaque or attenuating to the illumination radiation used in the lithographic process. Preferably, the substrate S₀ of the mask blank of the present invention has flat surfaces. In a preferred embodiment of the mask blank of the present invention, on a surface of the substrate S₀, an additional layer of Cr and/or modified Cr is formed. Advantageously, the substrate S₀ of the mask blank of the present invention is formed by a UV photosensitive alumino-boro-germano-silicate glass having composition comprising, expressed in terms of mole percentage, 1-6% of Al₂O₃, 10-36% of B₂O₃, 2-20% of GeO₂, 40-80% of SiO₂, 2-10 % of R₂O, where R is selected from Li, Na and K, and expressed in terms of weight percentage of the glass, 0-5% of F. Preferably, the glass has a composition comprising, expressed in terms of mole percentage, 2-6% of Al₂O₃, 20-30% of B₂O₃, 5-20% of GeO₂, 42-67% of SiO₂, 2-6% of R₂O, where R is selected from Li, Na and K, and expressed in terms of weight percentage of the glass, 0-5% of F. Preferably, the alumino-boro-germano-silicate glass is further loaded with H₂ molecules at a level of at least 10¹⁸ molecules/cm³.

The mask and method of the present invention can overcome the drawbacks of conventional phase-shifting masks in terms of cost, turnaround time and inspectability and repair.

Additional features and advantages of the invention will be set forth in the detailed description which follows, and in part will be readily apparent to those skilled in the art from the description or recognized by practicing the invention as described in the written description and claims hereof, as well as the appended drawing.

It is to be understood that the foregoing general description and the following detailed description are merely exemplary of the invention, and are intended to provide an overview or framework to understanding the nature and character of the invention as it is claimed.

The accompanying drawings are included to provide a further understanding of the invention, and are incorporated in and constitute a part of this specification.

### BRIEF DESCRIPTION OF THE DRAWINGS

In the accompanying drawings,

FIG. 1 is a schematic illustration of the operating principle of a traditional binary mask and a simple alternating aperture phase-shifting mask.

FIGS. 2A, 2B and 2C are a schematic illustration of the plan, side elevation (along line A) and end elevation (along line B) views, respectively, of an alternating aperture phase-shifting mask.

FIG. 3A is a schematic illustration of the operating principle of an attenuating phase-shifting mask.

FIG. 3B is a schematic illustration of the manufacture steps of an attenuating phase-shifting mask, using TiSiN as the attenuating phase-shifting material.

FIG. 4 is a schematic illustration of chromeless phase-shifting mask and alternating aperture phase-shifting mask in use.

FIGS. 5A, 5B, 5C and 5D are schematic illustration of the cross-sections of the index pattern designs of exemplary masks of the present invention.

FIGS. 6A, 6B and 6C are schematic illustration of the cross-section of chromeless phase-shifting masks in the prior art as compared to the mask of the present invention illustrated in FIGS. 5A, 5B and 5C, respectively.

FIGS. 7A and 7B are schematic illustration of the cross-section of the pattern designs of exemplary masks of the present invention having additional features on top of the substrate surface.

FIG. 8 is a schematic illustration of the cross-section of an alternating phase-shifting mask known in the prior art.

FIG. 9 is a schematic illustration a platinum furnace for melting an exemplary photosensitive glass of the present invention.

FIG. 10 is a diagram showing the optical transmittance in the deep UV of the spectrum of a 1-mm thick sample of an exemplary photosensitive glass of the present invention.

FIG. 11 is a diagram showing the index variation along the thickness of a sample glass plate for an exemplary photosensitive glass of the present invention before exposure to UV writing radiation.

FIG. 12 is a diagram showing the IR absorption of a hydrogen-loaded sample of an exemplary photosensitive glass of the present invention.

FIG. 13 is a schematic illustration of determination of the induced refractive index change (Δn) in a sample of an exemplary photosensitive glass of the present invention, by using chrome mask exposure.

FIG. 14A is a diagram showing the measured induced refractive index changes (Δn) of a sample of an exemplary photosensitive glass of the present invention after exposure to 50 mJ-Gr for various period of time, by using chrome mask exposure.

FIG. 14B is a diagram showing measured induced refractive index changes (Δn) of a sample of an exemplary photosensitive glass of the present invention after exposure to 70 mJ-Gr for various period of time, by using chrome mask exposure.

FIG. 15 is a diagram showing measured induced refractive index change (Δn) of a sample of an exemplary photosensitive glass of the present invention under a series of differing exposure conditions, by using interferometry.

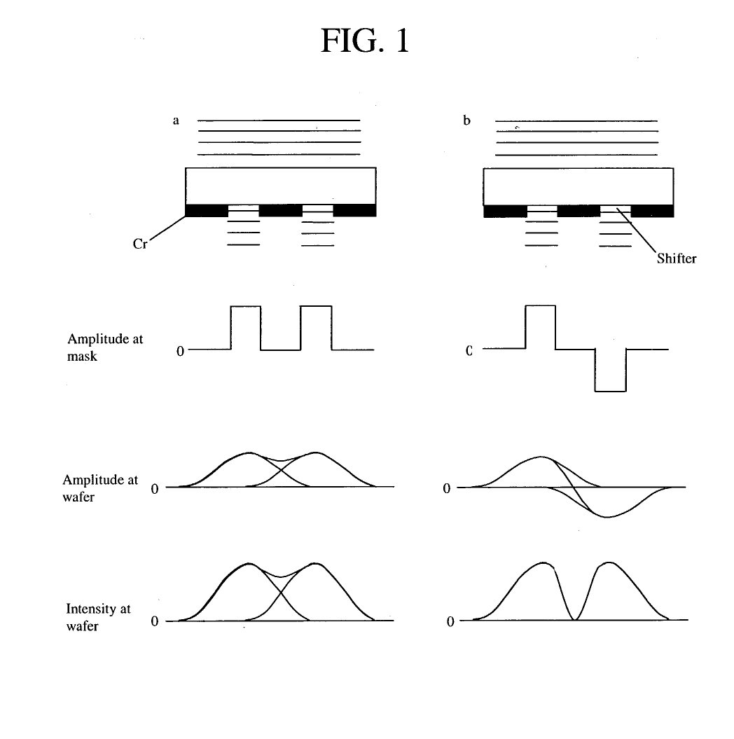

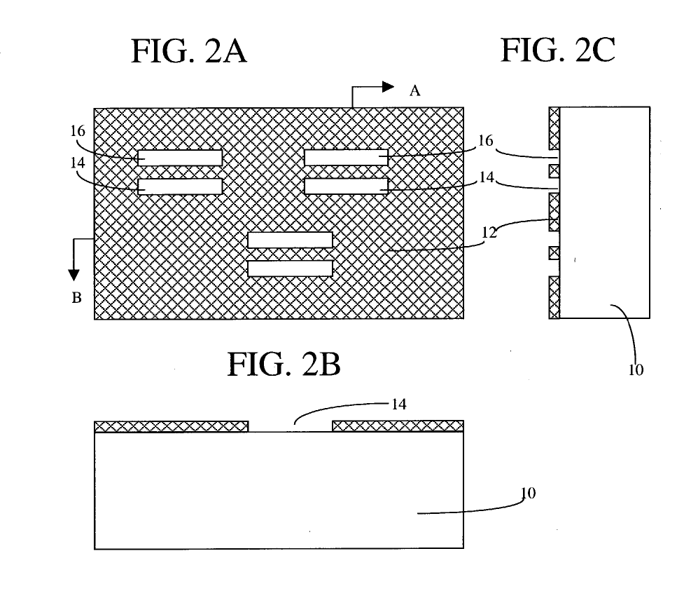

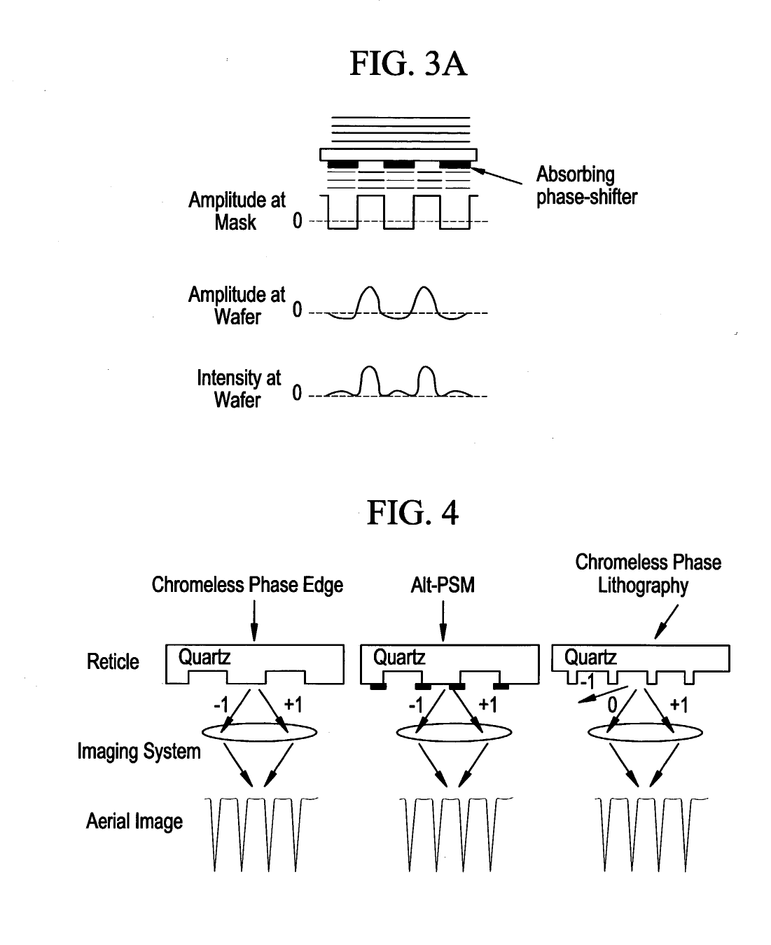

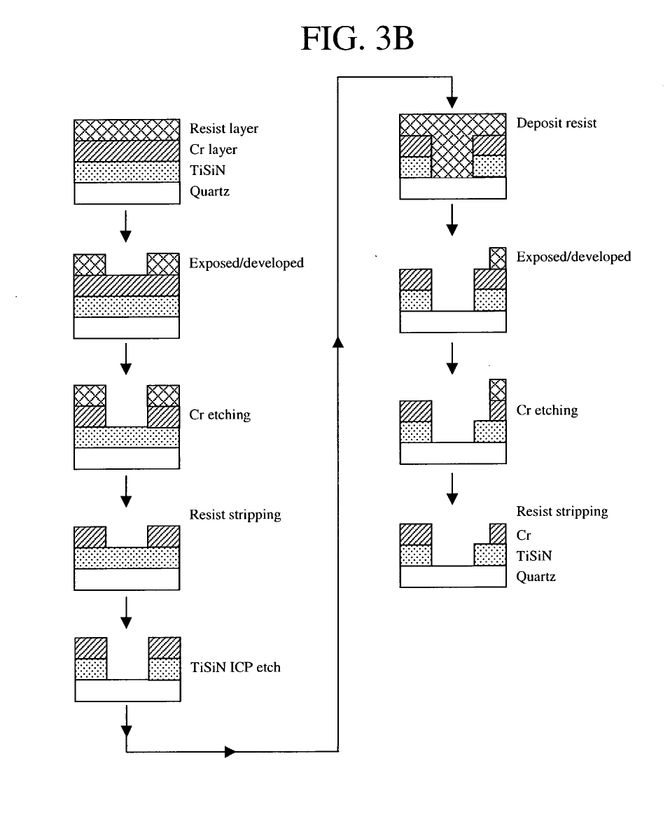

### DETAILED DESCRIPTION OF THE INVENTION

The literature concerned with the UV-photosensitive based fiber Bragg gratings in Ge-doped silica optical fibers is extensive. Although there is still some uncertainty and disagreement, it is generally regarded that there are two distinct mechanism responsible for the UV-laser induced refractive index change in this glass system. The first observed effect has as its origin in an oxygen deficient center (ODC) that has a characteristic absorption band at 240 nm. The defect is created during the fabrication process. For example, in the flame hydrolysis deposition process, the defect concentration can be directly related to the oxygen partial pressure during the consolidation step. This absorption associated with the GeODC is bleached by UV-light and is thought to lead to the refractive index change through a Kramers-Kronig effect. Schematically one can write the photoreaction in the following way:

$$[ \frac{O—Ge—Ge—O}{{—O—Ge}^{+ 2}} ] + ℏ ω ⇒ {—Ge}^{′} + {—Ge}^{+} + e \qquad ( 5 )$$

Here, the oxygen deficient center written in brackets are the two representations of the conjectured center. The GeE′ (analogous in structure to the Si E′ center) is readily observed by ESR and UV-spectroscopy after exposure. In general, there is a good correlation between the amount of GeE′ produced and the induced refractive index.

The more recently reported photorefractive effect requires the presence of a high concentration of dissolved molecular hydrogen in the glass. The hydrogen mediates a photoreaction that leads to a large induced absorption through SiOH (GeOH) formation as schematically indicated below:

—Si—O—Ge—+H₂+−ω [symbol] SiOH+GeH (6)

The induced index change correlates well with the amount of OH production as well as the strong induced absorption in the vacuum ultraviolet portion of the spectrum. It has been shown that the H₂-mediated effect does not require the oxygen deficient defect, although the presence of the defect can enhance the rate at which the refractive index develops with exposure.

The UV-photosensitivity effect has been almost exclusively limited to the silica-germania materials made by waveguide deposition techniques; in other words chemical vapor or flame hydrolysis processes have been typically used to produce materials that are photosensitive. It is not clear to which extent the UV-photosensitivity mechanism depends on the deposition process. Since it is not possible to melt these glass compositions (very high silica with 2.5-20 mol % GeO₂) by conventional glass melting, because of the high temperature required, it is difficult to answer this question. In pending U.S. patent application Ser. No. 10/186123, published as U.S. 2003/0029203 A1 by Borrelli et al., which is incorporated by reference herein in its entirety, a series of alumino-boro-germano-silicate photosensitive glasses were disclosed. According to this reference, the photosensitive alumino-boro-germano-silicate glasses, which are meltable, may have an induced refractive index change over 10⁻⁴ upon exposure to 248 nm UV light at a fluence in the order of mini joules/cm².

Photosensitive materials have been widely used in fiber Bragg gratings. The present inventors realized that the photosensitivity of these materials render them proper as a mask media for recording patterns in lithographic applications. By using UV radiation with a proper fluence and dosage, permanent index patterns may be created within the body of a photosensitive substrate. Such index patterns, when illuminated by the radiation in a lithographic process, can transfer image information onto an image-receiving substrate, such as a wafer. Such photosensitive material is particularly advantageous for phase-shifting masks.

In broad terms, the unconventional process of the present invention for creating a mask having a pattern P₀ transferable onto an image-receiving substrate by using a photosensitive material substrate comprises the following steps:

(a) providing a UV photosensitive substrate S₀ having a refractive index n₀ at the wavelength of the illumination radiation to which the mask is subjected to during the lithographic process;

(b) selectively exposing part of the surface of the substrate S₀ to UV radiation of less than 280 nm with an effective fluence for an effective amount of time, whereby producing a substrate S₁ consisting of (i) a UV induced index pattern P₁ having a modulated refractive index n₁, with n₁≠n₀, and (ii) parts P₂ that are not UV induced having a refractive index n₀; and

(c) optionally, forming pattern P₃ on a surface of the substrate S₀ or S₁ by depositing films of materials opaque or attenuating to the illumination radiation.

Steps (a) and (b) are different from the conventional process of making masks. It is to be noted that, if step (c) is involved in the process of the present invention, step (b) may be carried out before step (c), in which case pattern P₁ is formed first on the substrate S₀ of the mask blank, and pattern P₃ is formed afterwards. Alternatively, step (c) may be implemented before step (b), which means that features P₃ is formed first above the surface of substrate S₀, and the substrate S₀ bearing the pattern P₃ is subsequently exposed to patterning UV light, whereby pattern P₁ is formed. Either way, the patterns P₁ and P₃ combined to form the overall pattern P₀ of the mask. Of course, in certain cases, pattern P₃ may be dispensed with and the index P₁ will constitute the whole pattern P₀ of the mask.

The steps of the process are discussed in detail as follows. Other aspects of the present invention, including the mask, the mask blank, the photosensitive glass, of the present invention, are illustrated and can be understood by reference to the following description of the process for making the mask.

In step (a), the substrate S₀ differs from conventional mask substrates. In traditional photomasks, the standard substrate material was soda lime glass. Later, white crown was introduced to reduce defects. And still later, borosilicate glass was introduced to reduce temperature effects on the mask. Currently, as the lithographic wavelength has gone shorter, fused silica has been introduced for further temperature effects and to give better transmission. Features created in the mask involve etching the mask or deposition of layers above the surface of the substrate. In the present invention, S₀ is comprised of a photosensitive material within which pattern features can be created using proper selective UV exposure. Similar to the substrate in many conventional masks, the photosensitive substrate S₀ preferably has flat surfaces that meet the requirements of optical distortion in the lithographic processes in which the mask is used. For example, the surface of the substrate S₀ may be polished to a flatness of 1 to 2 μm peak to valley, or even a higher flatness where necessary. Of course, where necessary, the surface of the substrate S₀ may be engineered to have any specific topography prior to step (b) or (c) by using methods available in the prior art, such as dry etching and wet etching. The substrate S₀ preferably has a homogeneous composition and a substantially uniform refractive index n₀. The substrate S₀ should be transmissive to the illumination radiation used in the lithographic process. Preferably, at the lithographic wavelength of the lithographic process, the substrate should have a transmission of at least 70%, more preferably at least 75%, most preferably at least 80%. Preferably, the thickness of the substrate S₀ is sufficient in terms of the requirement for gravitation sag and pattern placement accuracy. Preferably, the substrate S₀ has a chemical durability that can withstand the mask producing environment, such as wet etching and dry etching.

Preferably, the substrate S₀ is formed by an alumino-boro-germano-silicate glass having a composition comprising, in terms of mole percentage, 1-6% of Al₂O₃, 10-36% of B₂O₃, 2-20% of GeO₂, 40-80% of SiO₂, 2-10% of R₂O, where R is selected from Li, Na and K, and expressed in terms of weight percentage of the glass, 0-5% of F. Preferably, the glass has an induced index change upon exposure to the patterning UV light Δn=n₁−n₀>1.0×10⁻⁴. For example, glasses having the following compositions listed in TABLE I at the end of the description of the present application may be used for the substrate S₀ of the mask of the present invention.

More preferably, the glass has a composition comprising, expressed in terms of mole percentage, 2-6% of Al₂O₃, 20-30% of B₂O₃, 5-20% of GeO₂, 42-67% of SiO₂, 2-6% of R₂O, where R is selected from Li, Na and K, and expressed in terms of weight percentage of the glass, 0-5% of F. This more preferred glass composition also constitutes one aspect of the present invention. It can be advantageously used in 248-nm photolithographic processes. The present inventors have unexpectedly found that glasses having composition within this range have a high chemical durability, in addition to a high induced refractive index change. These combined properties render the glasses particularly suitable for mask substrates, which typically undergo a series of chemical treatment during the manufacture of a mask. Most preferably, the glass has a composition comprising, expressed in terms of mole percentage, 2-6% of Al₂O₃, 23-27% of B₂O₃, 10-18% of GeO₂, 45-65% of SiO₂, 2-5% of R₂O, where R is selected from Li, Na and K, and expressed in terms of weight percentage of the glass, 1-4.5% of F. In a preferred embodiment of the alumino-boro-germano-silicate glass of the present invention, it has a composition, in terms of weight percentage, of approximately 44.2% SiO₂, 21.6% GeO₂, 4.50% Al₂O₃, 1.24% Li₂O, 0.974% Cl, 3.35% of F and 24.1 % of B₂O₃. Modulated index change Δn has been measured in this glass on the order of 2-3×10⁻⁴.

Preferably, the alumino-boro-germano-silicate glass is further loaded with H₂ molecules at a level of at least 10¹⁸ molecules/cm³. It is believed that the ability to load hydrogen molecules is dependent on the glass composition. It was observed that for the alumino-boro-germano-silicate glasses, loaded H₂ may contribute to a higher magnitude of induced refractive index change within the glass, although H₂ is not required for the photosensitivity.

Some glass compositions in TABLE I are loaded with hydrogen molecules and some are not. However, it is to be noted that those loaded with H₂ may be used with different H₂ load level or without H₂ being loaded, and that those without loaded H₂ may be further loaded with H₂.

It is preferred that the alumino-boro-germano-silicate glass for the masks of the present invention has a composition that has a fundamental absorption not over 300-nm, preferably not over 248-nm (5-eV). The fundamental absorption edge of pure silica, for example, is determined by the transition from the band consisting of the overlapping 2 p oxygen orbitals (valence band) to the band made up from the sp³ non-bonding orbitals of silicon (conduction band). The addition of alkali introduces another set of levels associated with non-bridging oxygen. When the concentration is high enough, a new band appears above that of the original valence band, thus moving the fundamental absorption edge to longer wavelengths. On the other hand, the addition of the network substitution ions such as boron, aluminum, and germanium has much less influence on the absorption edge. A high transparency of the glass of the UV light, such as 248-nm radiation, is preferred for the glass. Impurities such as transition metal ions or heavy metal ions that are inadvertently incorporated into glass, either from the batch materials, the containment crucible, the furnace or forming, must be kept to the <1 ppm level. These ions, even in small amounts have a dramatic adverse effect on the UV-absorption edge. Various constituents in the glass composition, such as Al₂O₃, B₂O₃, R₂O and F help producing a softer glass with a lower melting temperature. Preferably, the glass has a melting temperature lower than 1650° and a softening temperature of lower than 700° C.

Preferably, the substrate S₀ has a chemical durability that can withstand the chemical environment of the process of forming the mask of the present invention, such as the dry etching and/or wet etching steps where necessary. In this case, the additional features P₃ above the substrate S₁ can be formed directly on the upper surface of the substrate S₀/S₁. In case the substrate S₀/S₁ is not robust enough to resist the environment, it is contemplated that a very thin protective layer resistant to the environment, such as a silica layer, may be formed on the upper surface of the substrate S₀/S₁, and the additional features P₃ are formed on the surface of the protective layer. Of course, the protective layer should be transmissive to the lithographic radiation, as is required for the substrate S₀/S₁. As long as the thickness of the protective layer can prevent undesired etch of substrate S₀/S₁,the thinner the protective layer, the better. In addition, the protective layer should preferably have an even thickness and a low surface roughness in order not to create undesired wavefront distortion.

The substrate S₀ may be prepared to meet the requirements described supra, among others, then sold and used as mask blanks of the present invention. Alternatively, the substrate S₀ may be subject to part of step (c) in the process of the present invention, for example, deposition of a film opaque or attenuating above a surface thereof, and then sold or used a mask blank. For example and for the purpose of illustration only, a Cr layer or modified Cr layer used on conventional photomasks can be deposited on substrate S₀. As mentioned above, an intermediate protective layer, such as a silica layer, may be formed between the substrate S₀ and the additional opaque and/or attenuating layer, as long as it meets the requirements discussed above, where the substrate S₀/S₁ cannot resist the photomask producing environment. The resulting product may then be sold and used as photosensitive chrome mask blank, a type of the mask blank of the present invention. Usage of this type of mask will be described and illustrated infra. The deposition of such additional opaque or attenuating film can be effected using methods known in the art, such as sputtering, ion plating, and the like. The film may be further modified to obtain differing etching rate, reflectivity, etc. For example, where the additional opaque layer is Cr, it may be modified in accordance with U.S. Pat. Nos. 4,530,891 and 4,463,407, the relevant portion of which are incorporated herein by reference.

Where the mask blank is substrate S₀ itself without additional opaque or attenuating surface layer, step (b) can be implemented before step (c), if the optional step (c) is to be taken at all. In this case, it is preferred that step (c) is carried out on the surface to which the patterning radiation in step (b) is directly applied. The additional features P₃ thus are closer to the index pattern P₁ within the body of the substrate S₁. Needless to say, when the mask blank is a substrate S₀ covered by an additional layer of Cr on a surface thereof, step (c) need be carried out first in order to expose the surface of substrate S₀ before its patterning in step (b) can be implemented. This is because, it is preferred that the patterning radiation in step (b) is applied directly to the surface on which the additional features P₃ are created in step (c). It is also contemplated that steps ( b) and (c) may be carried out in various order for multiple times in order to create the desired final pattern.

Step (c) is carried out using conventional means available in the art. For example, where the additional features are chrome features, they can be formed by deposition of chrome layer where necessary (such as where step (c) is done after step (b) has been undertaken), preferably by sputtering, coating of a resist, exposure of the resist to patterning radiation, development of the resist, etching the chrome layer, etc.

In step (b), surface of the substrate S₀ is selectively exposed to UV writing light to create the pattern P₁. As mentioned supra, where step (c) is first carried out and additional features have been formed on a surface of substrate S₀, the patterning light in step (b) is directed to the exposed area of the surface of the substrate S₀.

The UV writing light has a wavelength capable of inducing refractive index change within substrate S₀. For the masks of the present invention, the writing light has a wavelength less than 280 nm. Preferably, the light source is a coherent laser source. For the alumino-boro-germano-silicate photosensitive glasses, the writing light can be advantageously 248-nm deep UV KrF excimer laser. It is noted that a tunable Nd/YAG laser which emits radiation at 268 nm and 270 nm could be used in place of the KrF excimer laser. Preferably, the light source provides a uniform intensity across the cross-section so that even writing can be obtained. In order to write patterns into the substrate S₀, sufficient radiation fluence and exposure time are required. It is found that for the photosensitive materials, the induced refractive index change (Δn) is a function of both radiation fluence and exposure time. However, over a certain limit of exposure time and exposure fluence, An tends to become saturated and remain constant. Typically, for alumino-boro-germano-silicate photosensitive glasses, in order to induce a meaningful index change at 248 nm, a fluence of at least 10 mJ/cm² is required. Preferably, the patterning UV light has a fluence of at least 20 mJ/cm², more preferably at least 30 mJ/cm², most preferably at least 40 mJ/cm². Typically, before the exposure dose reaches the saturating limit, at a lower fluence, to induce a given amount of index change for a given effective thickness of index pattern, more exposure time is required. Generally, the radiation dose in a stepper is too low, typically on the order of micro joules/cm², to induce a meaningful refractive index change in the glass.

Selective writing or patterning can be effected in various approaches. For example, one preferred approach involves using vector or raster scanning. The system for exposing resist in the manufacture of conventional mask can be adapted for use in the present invention for patterning the substrate S₀. Specifically, the desired pattern to be written into substrate S₀ is defined by an electronic data file loaded into a programmed exposure system which scans the writing laser beam in a raster or vector fashion across the exposed surface of substrate S₀. One such example of a raster scan exposure system is described in U.S. Pat. No. 3,900,737 to Collier. As the laser beam is scanned across the surface, the exposure system directs the beam at addressable locations on the surface as defined by the electronic data file. The laser beam may have fixed fluence, or it may further be equipped with a fluence modulator, which is programmed to adjust the fluence where necessary at given locations on the surfaces. Scanning speed may be varied to adjust the exposure time. As a result, index patterns having various dimensions can be created within the substrate S₀. In this approach, no resist or additional layers are required above the surface of substrate S₀. However, complex patterns having various shapes, width and length can be created. Another approach involves using photoresist. In this approach, similar to the manufacture of a conventional mask, a layer of resist is coated onto the surface of substrate S₀. Subsequently, the resist is exposed with patterns using well-known exposure systems described above. The resist layer is then developed to reveal only the portions of the surface of substrate S₀ to be patterned. With the remaining resist on, the substrate S₀ is then exposed to the patterning UV laser beam. After the pattern is created within the substrate, the remaining resist is stripped off. In this approach, electronic beam (E-beam) exposure system and corresponding resists can be used, and fine and precision patterns can be created. In a third approach, a contact or proximity mask may be used when exposing the substrate S₀ to the patterning light, thus eliminating the need of a complex scanning system. This approach is especially suitable for creating simple gratings.

The inventors have found that the induced refractive index change (Δn) along the depth or thickness of the index pattern is not always identical. For an unsaturated thick substrate having a thickness of 3 mm or 6 mm, the index pattern has an effective pattern depth or thickness d less than the substrate thickness. Along the effective thickness d, there is an index gradient. Typically, the area adjacent to the surface of S₀ to which the exposure light is directly applied has the highest refractive index change, and the lowest portion of index pattern has the same index as substrate S₀. Without intending to be bound by any particular theory, the inventors believe this is because the patterned glass is not subjected to the same radiation fluence along the pattern depth because of light absorption along the light path. Therefore, in the context of and for the purpose of the present application, the refractive index n₁ of the induced index pattern P₁ is an modulated index along the effective thickness d of the index pattern. Assume at a given thickness t (0≦t≦d) measured from the surface of the substrate, the refractive index of pattern P₁ is a substantially uniform number n(t), then the total phase shift (s) caused by the index pattern P₁ along the whole effective thickness d can be expressed as follows:

$$s = 2 π \frac{{\int }_{0}^{d} ( n ( t ) - {n}_{0} ) ) ⅆ t}{λ} = \frac{2 π ( {n}_{1} - {n}_{0} ) \cdot d}{λ} \qquad ( 7 )$$

Thus, the modulated refractive index n₁ is

$${n}_{1} = {n}_{0} + \frac{1}{d} {\int }_{0}^{d} ( n ( t ) - {n}_{0} ) ) ⅆ t \qquad ( 8 )$$

A great advantage of the process of the present invention in creating mask is, by carefully adjusting radiation fluence and exposure time, both effective thickness d of the index pattern and the refractive index change Δn=(n₂−n₁) can be adjusted. Thus a gray-scale mask with an index pattern having arbitrary distribution of d and Δn can be produced. Through the entire effective thickness d of the index pattern, phase shift s=2π·d·Δn/λ of the radiation illumination from 0 to kπ (where k is a positive integer) can be obtained. Of particular interest is s≈π, where the mask is a near 180° phase-shifting mask. Ideally, s=π. However, practically, it is difficult, if not impossible, to always obtain a strict 180° phase shift. Thus, in the context of the present application, a 180° phase shift or a near 180° phase shift is meant to be within the range of 180±5°, preferably 180±2°. For certain area of the mask, where any arbitrary phase shift amount is desired, d and Δn can be adjusted by tuning the radiation fluence and changing exposure time to reach the goal.

Another advantage of the process for making the masks of the present invention lies in the ease of correction of defects. Defects in the index pattern uncovered in inspection can be easily corrected by using additional exposure. Alternatively, selective etching of the substrate of the defective area may be used to make the necessary correction as well.

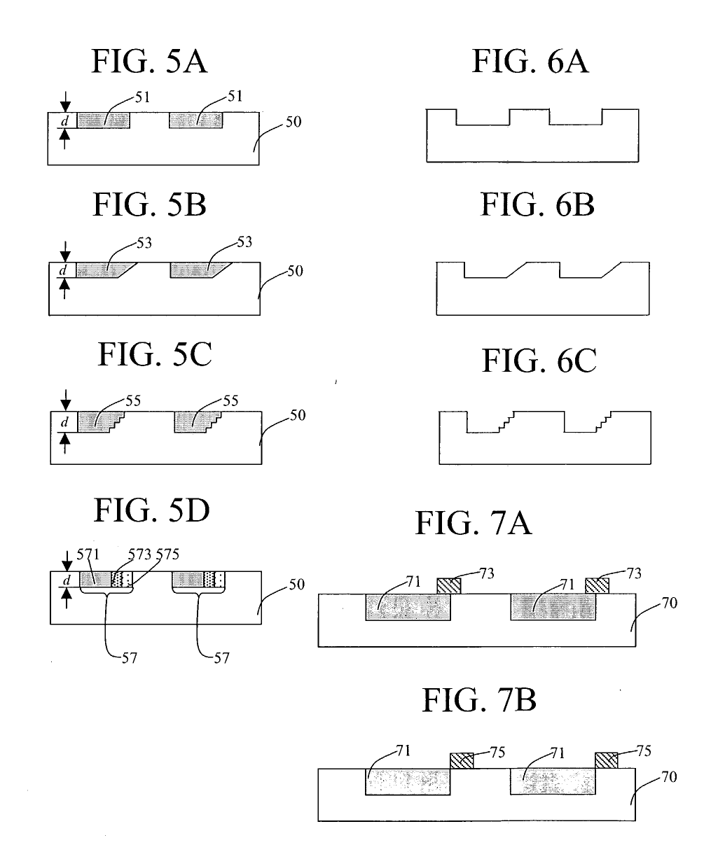

FIGS. 5A-5D illustrate schematically the cross-section of some simple phase-shifting mask designs of the present invention. Additional pattern features P₃ above the substrate surface, if any, are not shown. In a glass substrate 50 having flat surfaces and a refractive index n₀, phase shift features P₁ 51, 53, 55 and 57 are created via selective exposure to UV writing radiation. The phase shift features P₁ have an effective depth of d. In FIG. 5A, the 180° shifting pattern 51 has steep edges. In FIG. 5B, the 180° shifting pattern 53 has a continuously tapering edge with a tapering thickness. In FIG. 5C, pattern 55 has a step-wise tapering edge with a tapering thickness. In FIG. 5D, pattern 57 is comprised of several portions 571, 573 and 575 having substantially the same effective thickness d, but each having a differing modulated refractive index n₁₁, n₁₃, and n₁₅, respectively, with n₁₁<n₁₃<n₁₅ and d·(n₁₁−n₀)≈λ/2. Thus 571 creates a near 180° phase shift, whereas 573 and 575 creates a gradient in terms of phase shift. The function of the tapering edges of patterns 53 of FIG. 5B and 55 in FIG. 5C is similar to portions 573 and 575 in FIG. 5D. These phase shift gradient features are sometimes desired in phase-shifting masks, because the sharp edges of pattern 51 in FIG. 5A may be printable to the image-receiving substrate, such as a wafer.

The phase shift features 51, 53, 55 and 57 can all be realized by modulated UV scan of the photosensitive substrate 50 with relative ease, with limited number of scanning steps, possibly in one scan operation. Of course, where necessary, gray-scale masks can be used in creating the sloping edges of 53 and stepwise edge of 55 and the phase shift gradient 57. Also, as mentioned above, the features may be created with the aid of photoresist as well. However, in any event, the creation of these photomasks are far simpler than the chromeless phase-shifting masks described in the prior art. FIGS. 6A-6C illustrates schematically the chromeless phase-shifting masks similar in operating principle to the present inventive FIGS. 5A-5C masks. In creating the FIG. 6A mask starting from fused silica substrate, the following steps are required: deposition of Cr layer; deposition of resist; exposure and development of resist; selective etching of Cr; selective etching of silica; stripping of resist; and stripping of Cr layer. This is far more complex and far more expensive than the creation of FIG. 5A feature. Even if patterns 51 in FIG. 5A are created with the aid of resist, the production of FIG. 5A mask is still much simpler in that it does not involve the metalization and silica etching steps. The production of FIG. 6B chromeless phase-shifting mask requires the use of a special material having gradient etching rate, in addition to the steps for the FIG. 6A mask. The small step-wise features of FIG. 6C requires multiple steps of photoresist deposition, exposure and development, as well as multiple steps of selective etching of Cr and silica, which are too complex to be feasible and practical.

FIGS. 7A and 7B illustrate schematically the cross-section of some of the embodiments of the mask of the present invention having additional features P₃ above the index pattern P₁. In FIG. 7A, chrome features 73 are added on top of the surface of the substrate 70. Some of these chrome features may cover the edge of the phase-shifting index pattern features 71. Similar to conventional phase shifting design, this type of design in FIG. 7A has some advantages. This type of design should typically be formed by performing step (b) of the process of the present invention first on a substrate S₀ without pre-formed chrome layers to create the phase shifting features, followed by creating the chrome opaque features in step (c). In FIG. 7B, chrome features 75 are formed adjacent to the edge of the phase shifting features 71 but without overlapping. Since this design does not require the phase shifting feature to extend under the surface features, it can be formed by forming either features 71 or 75 first. Thus this mask may be created by using a mask blank having pre-formed chrome layer. It is to be understood that, though the additional surface features P₃ are illustrated in these figures as chrome layer, other opaque or attenuating layers, 180° phase shifting or not, may be employed in conjunction with the opaque chrome layer, to create complex surface pattern designs where necessary. These features, together with the phase shifting index patterns in the substrate of the mask of the present invention, supplement and/or mutually correct each other to form a pattern transferable to the image-receiving substrate, such as a wafer.

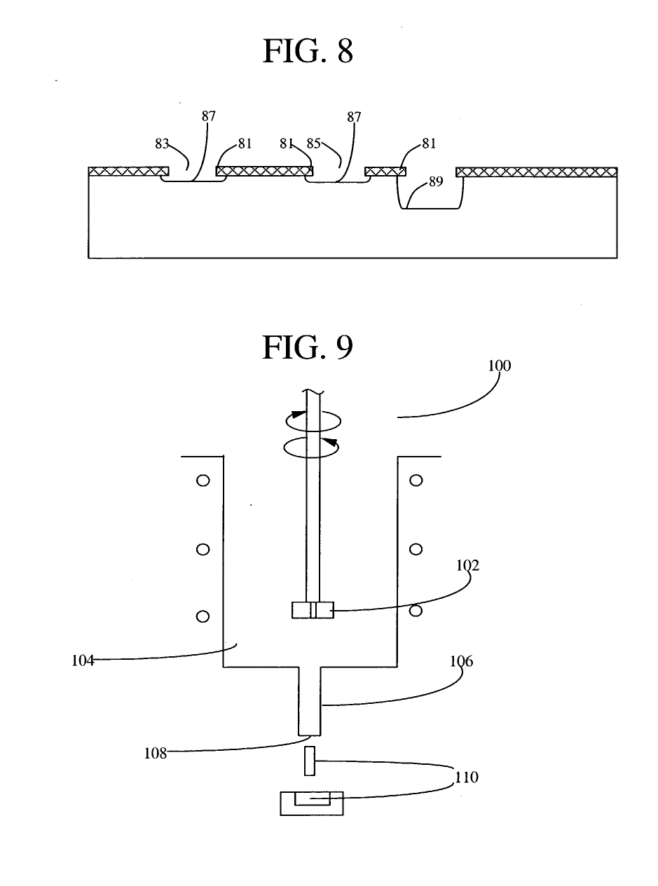

Again, the production of the FIGS. 7A and 7B masks is far simpler than the production of conventional phase-shifting masks operating under the similar principle. Also the produced masks have advantages over those of the prior art. FIG. 8 illustrates schematically the design of a conventional PSM corresponding to that of FIG. 7A. In FIG. 8, in order to ensure that the two types of aperture perform identically in an optical sense, except for the phase-shift, the substrate is etched back laterally under the opaque film, thus leaving the opaque film unsupported at the edge. The non-phase shifting apertures 83 and 85 and the phase shift apertures are noted. The trenches 87 and 89 etched in the substrate beneath the apertures are necessarily formed after the apertures are etched in the opaque layer, which is a high-cost process. The requirement to form a second custom pattern—by a process that can result in uncorrectable defects—significantly raises the cost of producing this type of conventional alternating aperture PSMs.

Various electronic design automation tools are known for preparing the patterns used in conventional and phase-shifting masks. In addition, OPC tools alter those patterns to account for the realities of the exposure systems. It is also known that the pattern of apertures on the phase-shifting mask need not correspond closely to the ultimate circuit pattern, at least not when a conventional block-out mask is employed for a second exposure on the resist film in concert with a first exposure made using a an alternating-aperture PSM. Such second exposures erase anomalies due to phase-conflicts. All these tools and strategies developed for conventional masks, phase-shifting or not, can be adapted for use in the production and use of the mask of the present invention.

A specific example of the mask of the present invention involves a grating index pattern. The index pattern is a 180° phase shifting 1-D or 2-D grating system created by scanning the photosensitive substrate or by exposing it using a phase mask. The grating pitch can be less than 300 nm, and may be as short as 200 nm. These low pitch gratings can be used for creating very dense sub-wavelength features. A mask of the present invention may be a photosensitive substrate having such grating index patterns embedded therein. Such mask can be used in conjunction with trim mask and/or chrome binary masks via multiple exposure to create desired image patterns on an image-receiving substrate, such as a wafer. The trim mask can be a phase-shifting trim mask produced using the method of the present invention, or a conventional chrome trim mask. Advantageously, an additional feature P₃ formed by chrome or other weak phase shifting materials, is formed on top the photosensitive mask substrate in which the grating is formed. An apparent advantage of this type of composite mask is that multiple exposure may be avoided or at least exposure steps can be reduced.

The following non-limiting example further illustrates the present invention.

### EXAMPLE

In this example, an alumino-boro-germano-silicate glass having the composition of glass 18 in TABLE I was melted and characterized. The sample was prepared from the melted glass and subjected to UV writing radiation. A Bragg grating was created inside the sample and characterized.

High purity SiO₂, GeO₂, Al(OH)₃, Li₂CO₃, LiCl, LiNO₃, AlF₃ and B₂O₃ were used as the batch materials. The batch powder mixture after ball milling was charged into a platinum furnace 100, shown in FIG. 9 where it was melted at 1700° C. for 16 hours. Furnace 100 includes a stirrer 102 for stirring glass melt 104 to provide a homogeneous glass melt. Furnace 100 includes a down corner 106 and a down corner orifice 108 for delivering a bulk glass body 110. Bulk glass bodies 110 were made with a general dimension of 105×4×4 inches (3.81×10.16×10.16 cm) and annealed at 437° C. The annealed bulk glass bodies 110 were cut, finished, and polished to provide small bulk glass bodies 120 having a rectangular block shape. Bulk glass bodies 120 had a dimension of 5×5×3 mm³.

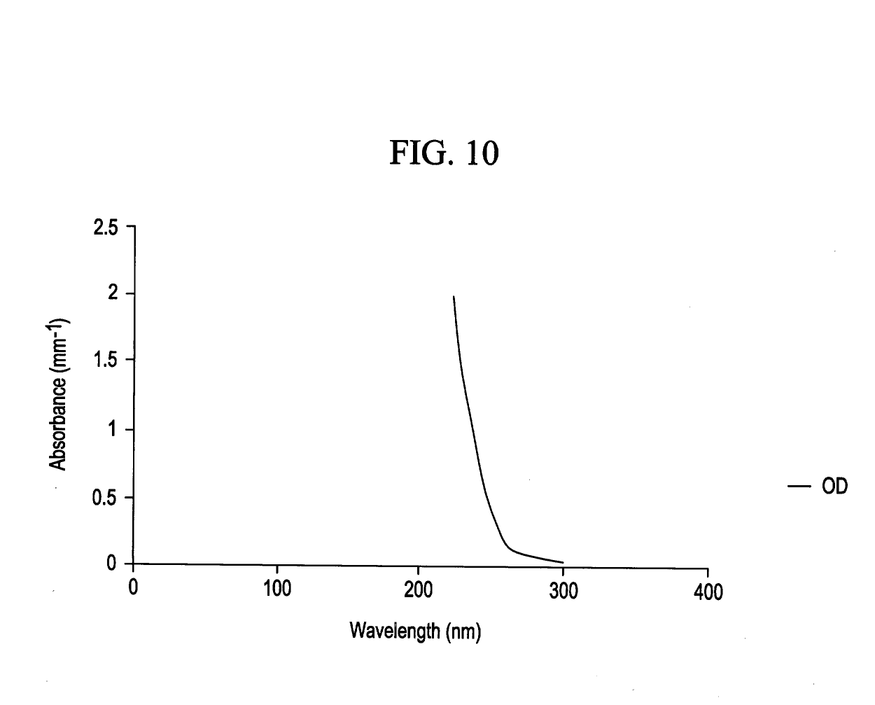

The optical transmittance through a 1-mm thick sample in the deep UV portion of the spectrum is shown in FIG. 10. The optical quality of the glass was then characterized by an interferometric measurement of the optical phase front.

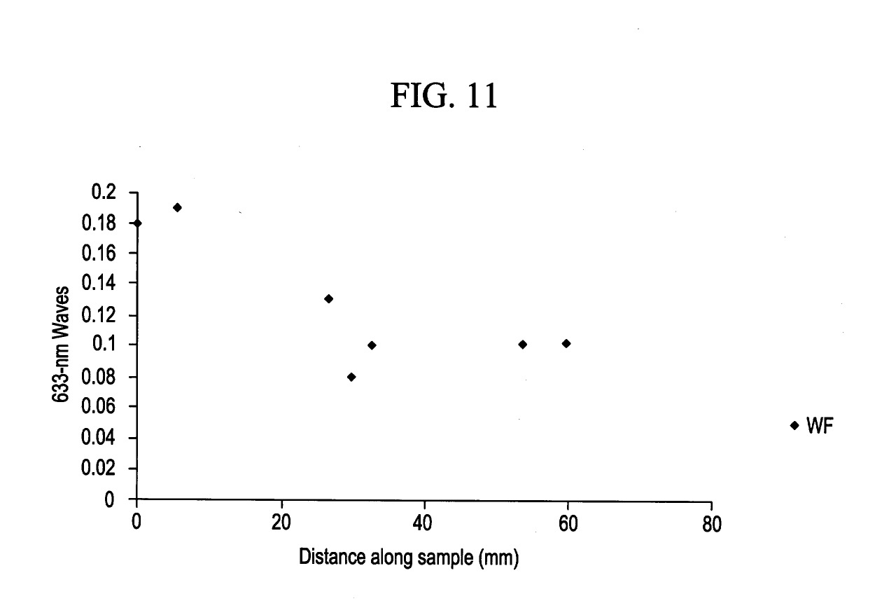

Index variation through the thickness direction was then studied by preparing a cross-section sample. The sample was 60-mm long and 6-mm wide. This width then was the original unfinished thickness of the glass patty. The phase front at a number of positions along the 60-mm length was then measured. To remove the surface effects only the total peak-to-valley wavefront distortion of the inner 4-mm was reported. The results were shown in FIG. 11. Dots shown in the diagram are wavefronts (WF). There was some variation, but in average was about 0.1λ/mm, which would correspond to a peak-to-valley index variation of 6×10⁻⁵.

Samples for test of photosensitivity were ground and polished to obtain 1/10-wave flatness and a thickness of 1 mm. The samples were cut into 1×2cm² wafers. The long edges were polished as well.

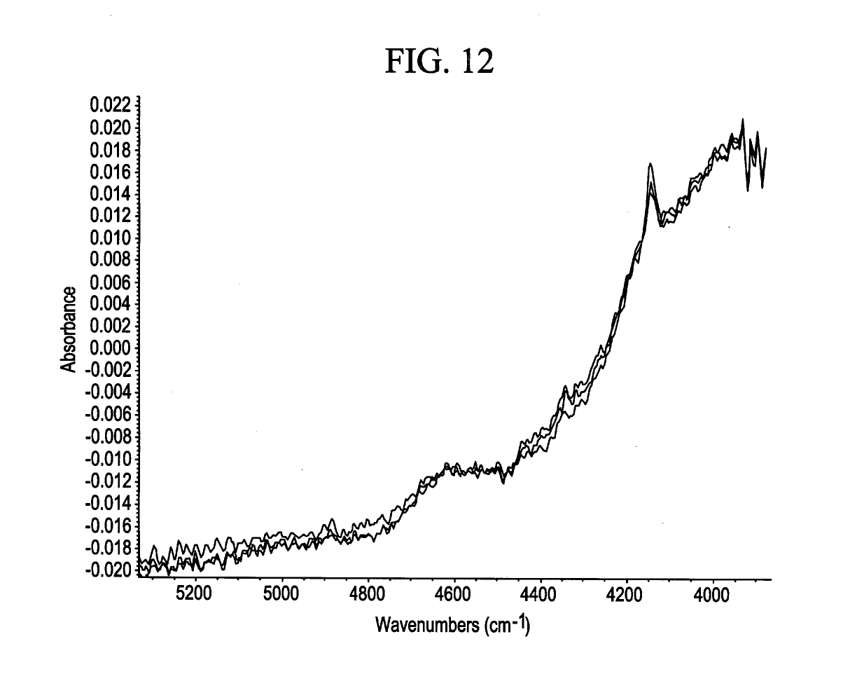

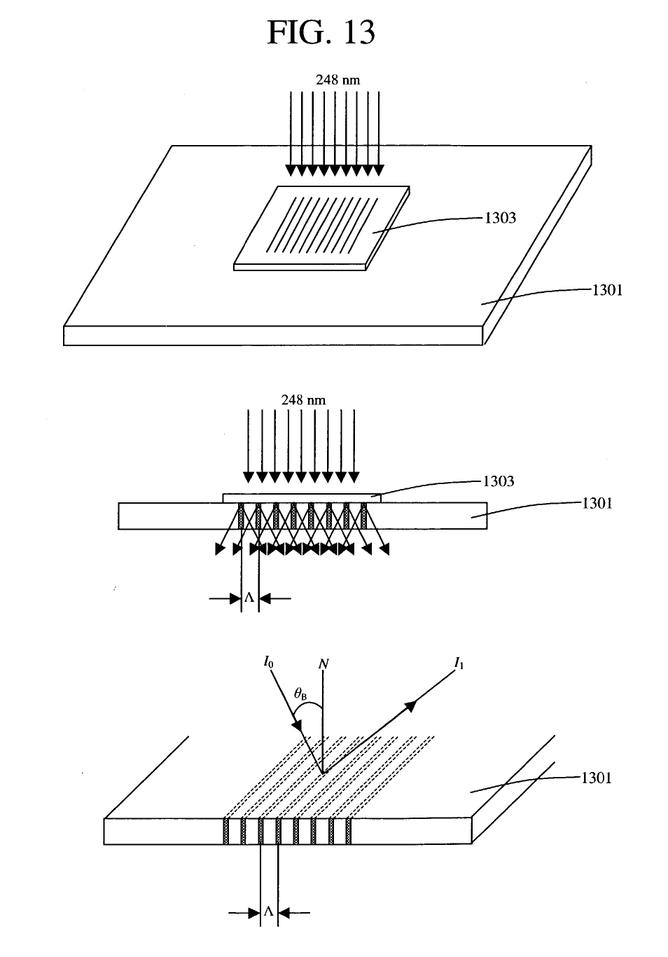

The samples were loaded with molecular hydrogen at a pressure of 100 atm in a pressure vessel at 200° C. For this thickness, the diffusion time to achieve 95% of the ambient at the mid-plane was approximately 3 days. The molecular hydrogen concentration was determined from the magnitude of the IR absorption peak at 4126 cm⁻¹ which corresponds to the hydrogen stretching vibration. This is shown in FIG. 12 where one can also see that the peak height diminishes with exposure indicating the progression of the photo-reaction. The absorption showing H₂ vibration can be used to calibrate H₂ concentration in the sample.

The sample was then exposed to UV writing light. The exposures were primarily done using the DV Lumonics 600 KrF excimer laser operating at 248 nm. The full beam is rectangular in shape, approximately 1 cm by 2 cm having a gaussian distribution in the shorter direction. The intensity was estimated by measuring the power through a 3-mm round aperture, positioned in the middle of the output beam. Also used was a Lambda-Physik Compex-150 laser. This laser had an optical configuration that produces a 1-mm spatial coherence length, as compared to <0.1-mm for the Lumonics.

The exposure was done in a number of ways: (1) contacting with a chrome Ronchi ruling with a 20 μm period; (2) contacting, or near contacting with a 248-nm phase mask; and (3) exposing through a 2-mm aperture.

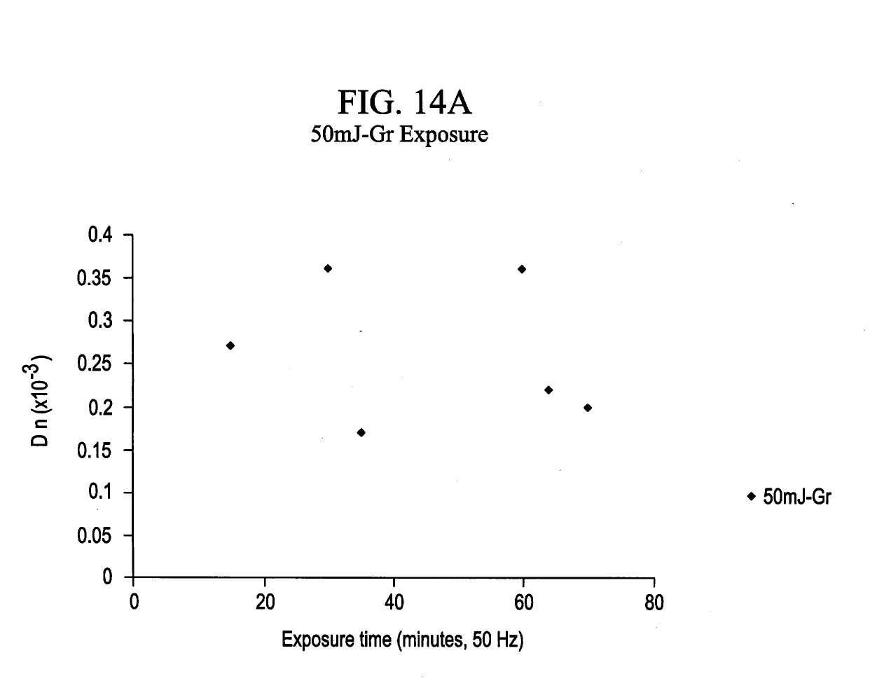

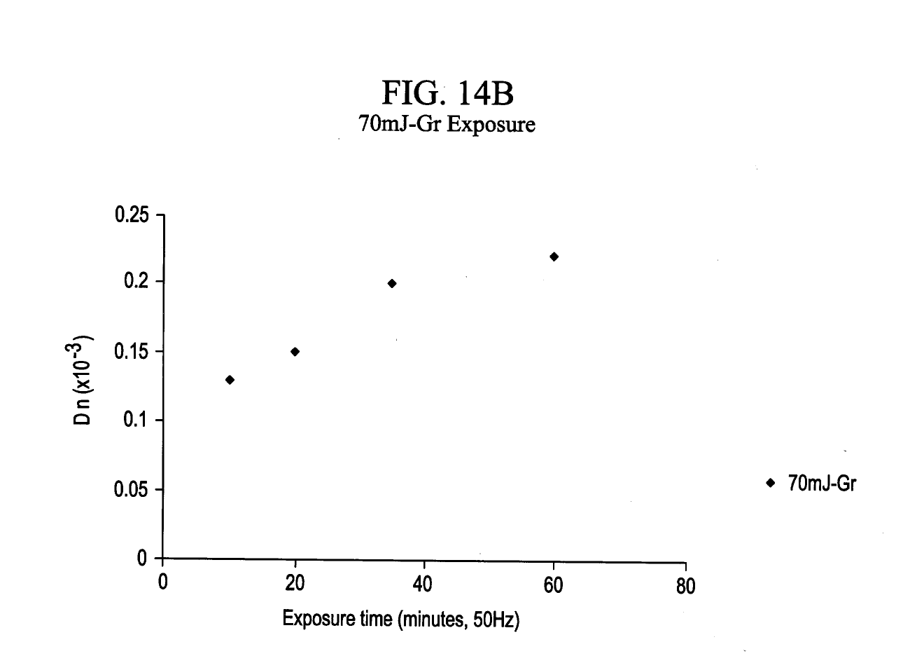

The determination of the induced refractive index was done in a number of different ways. For the chrome mask exposures, the induced refractive index was measured from the diffraction efficiency appropriate for a holographic grating whose fringes were perpendicular to the surfaces as shown in FIG. 13. In FIG. 13, 1301 is the glass sample, and 1303 is the chrome mask. I₀ is the incident beam, and I₁ is diffracted beam. The angle (θ_{B}) with respect to the normal (N) that satisfied the Bragg reflection condition is the following:

$$sin {θ}_{B} = \frac{λ / {n}_{0}}{2 Λ} \qquad ( 9 )$$

where Λ is the pitch of the grating which in the test was 1 μm, the reading wavelength λ was 0.633 μm, and the refractive index of the glass n₀ was 1.48. For this large pitch of the grating the angle to satisfy the Bragg condition is quite small, on the order of 1 degree. The sample was mounted on a precision rotating stage and the diffraction efficiency was maximized. From that number the modulated induced refractive index (Δn) was obtained through the expression for the diffraction efficiency (Eff) of a thick phase grating:

$$Eff = {sin}^{2} \frac{π Δ nL}{λ cos {θ}_{B}} \qquad ( 10 )$$

where L is the grating index. The calculated value of Δn for a number of different exposure conditions using this method is shown in FIGS. 14A and 14B. The induced index change Δn was above 1×10⁻⁴ for an exposure fluence of 50 mJ/cm² for over 10 minutes.

In using equation (10), a factor that needs to be taken into consideration is the determination of the appropriate thickness to use. The samples have linear absorption at the excitation wavelength and hence the exposure is not constant through the entire sample thickness. Although grating was observed through the 1-mm thickness of the sample exposed, the index modulation might not be constant. Fortunately, the induced index variation with exposure fluence is not overly strong. Also the effect at a given fluence tends to saturate with exposure time. Since the induced effect is essentially a fluence dominated effect, and tends to saturate, then with long enough exposure the variation in the modulated induced index with depth can be minimized.

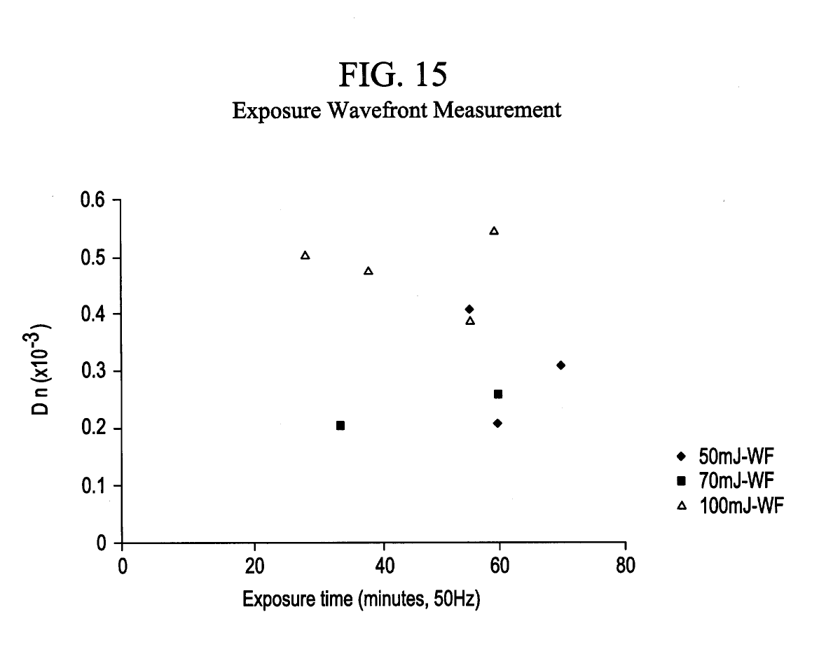

A more direct method to measure the induced refractive index is to use interferometry. The interferometer traces of the wavefront distortion using oil on flats to compensate for any surface change were measured for a number of different exposures comparable to those used to make the gratings. The induced refractive index change derived from this measured phase distortion in 633-nm waves, Δ(nL) is shown in FIG. 15 for three exposure fluence. One should bear in mind that this measured the total index change whereas the grating method measures the modulated index change which is half that of the peak-to-valley change.

Birefringence measurement was also done on the exposed spots to ascertain the amount of the refractive index change that resulted from the induced volume change. One can convert the measured birefringence to overall refractive index change produced by the densification. The comparison to the total refractive index change measured value from wavefront to that calculated from the birefringence is of the order of 0.5. It is clear that a significant portion of the index change was produced from the volume change.

Another test was performed using a phase mask. The phase mask was that made to produce a fiber Bragg grating at 1500-nm, thus it had a pitch of 1 μm. This made the Bragg angle about 12 degrees as measured from the normal to the top face. These exposures required the use of the Compex 150 Lambda-Physik laser which had the extended spatial coherence length. The beam was modified to produce a uniform intensity profile over a 1-mm width, which was required by the reading beam size. In this process one lost quite a bit of energy, so the exposures were of the order of 10-20 mJ/cm², and consequently the exposure times were relatively long. The resulted induced modulated index change was compared to that determined from the diffraction efficiency of the holographic grating and that determined from the interferometry. The agreement was within a factor of two.

In a glass sample, a grating having a pitch of 250 nm was created using a phase mask.

While the UV exposure experiments described in this Example have used hydrogen loading to increase the photosensitivity of the glasses, it is noted that the glass of this Example is also photosensitive in the absence of hydrogen and at low hydrogen loading levels. The glass with no/low hydrogen loading may require a longer exposure time or higher exposure fluence to achieve a given index change.

It will be apparent to those skilled in the art that various modifications and alterations can be made to the present invention without departing from the scope and spirit of the invention. Thus, it is intended that the present invention cover the modifications and variations of this invention provided they come within the scope of the appended claims and their equivalents.

TABLE I

| | Glass No. | | | | | | | | | | | | | | | | | |
|---|---|---|---|---|---|---|---|---|---|---|---|---|---|---|---|---|---|---|
| | 1 | 2 | 3 | 4 | 5 | 6 | 7 | 8 | 9 | 10 | 11 | 12 | 13 | 14 | 15 | 16 | 17 | 18 |
| SiO₂ | 62.5 | 57.5 | 47.5 | 43.4 | 51.6 | 56.6 | 54.1 | 62.8 | 61.6 | 54.0 | 56.6 | 56.6 | 54.0 | 51 | 66.2 | 75.7 | 78.5 | 53.4 |
| GeO₂ | 2.5 | 2.5 | 2.5 | 15.0 | 7.5 | 2.5 | 5 | 6.25 | 7.5 | 2.5 | 2.5 | 2.5 | 2.5 | 7.5 | 5 | 5 | 5 | 15.0 |
| Li₂O | — | — | — | 3.20 | 2.6 | 2.6 | 2.6 | 2.6 | 2.6 | 2.6 | — | — | 5.2 | 3.2 | 7.0 | 0.1 | — | 3.00 |
| Na₂O | 2.5 | 5 | 10 | — | — | — | — | — | — | — | 2.6 | — | — | — | 0.5 | 4.8 | 4.0 | |
| K₂O | — | — | — | — | — | — | — | — | — | — | — | — | — | — | — | — | — | |
| Al₂O₃ | 2.5 | 5 | 10 | 3.20 | 3.20 | 3.20 | 3.2 | 3.2 | 3.2 | 3.2 | 3.2 | 3.2 | 3.2 | 3.2 | 2.1 | 1.2 | 1.4 | 3.2 |
| B₂O₃ | 30 | 30 | 30 | 35.1 | 35.1 | 35.1 | 35.1 | 25.1 | 25.1 | 35.1 | 35.1 | 35.1 | 35.1 | 35 | 17.5 | 13.2 | 11.1 | 25.1 |
| H₂ (×10¹⁸) | 5 | 3.7 | 0.26 | 5 | 5 | — | — | — | — | — | — | — | — | — | 2.5 | 2.5 | 2.5 | — |
| Δn (×10⁻⁴) | | | | | | | | | | | | | | | | | | |

What is claimed is:

1. A mask having a pattern P₀ transferable onto an image-receiving substrate when subjected to illumination radiation in a lithographic process, comprising a UV photosensitive substrate S₁ consisting of (i) a UV induced index pattern P₁ and (ii) parts P₂ that are not UV induced, wherein the index pattern P₁ has a refractive index n₁ at the wavelength of the illumination radiation, the non-UV induced parts P₂ has a refractive index at the wavelength of the illumination radiation n₀, with n₀≠n₁, and n₀ and n₁ remain substantially unchanged when the mask is exposed to the illumination radiation during the lithographic process.

2. A mask in accordance with claim 1, wherein n₁−n₀>1×10⁻⁴.

3. A mask in accordance with claim 1, wherein the index pattern P₁ has an effective thickness d chosen to create a 180° phase-shift of the illumination radiation used in the lithographic process with respect to the non-UV induced parts P₂.

4. A mask in accordance with claim 3, wherein the index pattern P₁ has an edge with a tapering gradient in terms of phase shift.

5. A mask in accordance with claim 4, wherein the index pattern P₁ has an edge with a tapering gradient in thickness effecting the tapering gradient in phase shift.

6. A mask in accordance with claim 5, wherein the thickness gradient of the edge is stepwise.

7. A mask in accordance with claim 5, wherein the thickness gradient of the edge is continuous.

8. A mask in accordance with claim 4, wherein the index pattern P₁ has an edge consisting of parts having different refractive indexes effecting the tapering gradient in phase shift.

9. A mask in accordance with claim 1, wherein the index pattern P₁ has an arbitrary distribution of phase shift amount.

10. A mask in accordance with claim 1, wherein the index pattern P₁ is a grating having a pitch of less than 300 nm.

11. A mask in accordance with claim 10, wherein the thickness of the index pattern P₁ is chosen to create a 180° phase shift of the illumination radiation during the lithographic process with respect to the non-UV induced parts P₂.

12. A mask in accordance with claim 1 comprising, above a surface of the substrate S₁, pattern features P₃ formed by layers of materials opaque or attenuating to the illumination radiation used in the lithographic process.

13. A mask in accordance with claim 12, wherein pattern features P₃ are formed above the surface of substrate S₁ closer to the index pattern P₁.

14. A mask in accordance with claim 12, wherein at least part of features P₃ is formed by Cr or modified Cr.

15. A mask in accordance with claim 12, wherein at least part of features P₃ is formed by attenuating material chosen to have a refractive index and thickness to create a 180° phase shift of the illumination radiation with respect to the ambient atmosphere in which the mask is placed during the lithographic process.

16. A mask in accordance with claim 12, wherein the features P₁ and P₃, when transferred together to the image-receiving substrate during the lithographic process, supplement and correct each other to form the desired image on the image-receiving substrate.

17. A mask in accordance with claim 1, wherein the substrate S₁ is formed by UV photosensitive alumino-boro-germano-silicate glass, said glass comprising, expressed in terms of mole percentage, 1-6% of Al₂O₃, 10-36% of B₂O₃, 2-20% of GeO₂, 40-80% of SiO₂, 2-10% of R₂O, where R is selected from Li, Na and K, and expressed in terms of weight percentage of the glass, 0-5% of F.

18. A mask in accordance with claim 17, wherein the alumino-boro-germano-silicate glass is further loaded with molecular hydrogen at a level of at least 10¹⁸ molecules/cm³.

19. A mask in accordance with claim 17, wherein the alumino-boro-germano-silicate glass comprising, expressed in terms of mole percentage, 2-6% of Al₂O₃, 20-30% of B₂O₃, 5-20% of GeO₂, 42-67% of SiO₂, 2-6% of R₂O, where R is selected from Li, Na and K, and expressed in terms of weight percentage of the glass, 0-5% of F.

20. A process for making a mask having a pattern P₀ transferable onto an image-receiving substrate when subjected to illumination radiation in a lithographic process, comprising the following steps:
(a) providing a UV photosensitive substrate S₀ having a refractive index n₀ at the wavelength of the illumination radiation to which the mask is subjected to during the lithographic process;
(b) selectively exposing part of the surface of the substrate S₀ to UV radiation of less than 280 nm with an effective fluence for an effective amount of time, whereby producing a substrate S₁ consisting of (i) a UV induced index pattern P₁ having a modulated refractive index n₁, with n₁≠n₀, and (ii) parts P₂ that are not UV induced having a refractive index n₀; and
(c) optionally, forming pattern P₃ above a surface of the substrate S₀ or S₁ by using materials opaque or attenuating to the illumination radiation.

21. A process in accordance with claim 20, wherein in step (b), the fluence and wavelength of the UV radiation used to pattern the substrate S₀, as well as the exposure time are chosen such that the effective thickness d and refractive index n₁ of index pattern P₁ meet the following requirement:
d·(n₁−n₀)≈λ/2
where λ is the wavelength of the illumination radiation used in the lithographic process, thereby the pattern P₁ creates a 180° phase shift of the illumination radiation with respect to the non-UV induced parts P₂.

22. A process in accordance with claim 20, wherein in step (b), the fluence or the UV radiation used to pattern the substrate S₀ and/or exposure time are chosen such that the edge portion of the index pattern P₁ has a tapering gradient in terms of phase shift amount.

23. A process in accordance with claim 20, wherein the fluence of the UV radiation for patterning the substrate S₀ is adjusted by tuning the fluence of the radiation source.

24. A process in accordance with claim 20, wherein the fluence of the UV radiation for patterning the substrate S₀ is adjusted by using gradient attenuating mask.

25. A process in accordance with claim 20, wherein in step (b), a contact or proximity phase mask is used for selectively exposing the substrate S₀ to the patterning UV radiation.

26. A process in accordance with claim 20, wherein in step (c), additional features are formed above the surface of S₁ to which the UV patterning radiation has been or is to be directly applied in step (b).

27. A process in accordance with claim 20, wherein step (c) comprises depositing a film of a material opaque or attenuating to the illumination radiation used in the lithographic process above a surface of substrate S₀ or S₁, depositing photoresist on top of the opaque/attenuating film, exposing the photoresist, developing the exposed photoresist, selectively etching the opaque/attenuating film, followed by stripping the remaining photoresist, whereby additional pattern features P₃ of the opaque/attenuating material are formed.

28. A process in accordance with claim 20, wherein in step (c), where an attenuating material is used to form the additional features, its refractive index at the wavelength of the illumination radiation used in the lithographic process and its thickness are chosen such that the film creates a 180° phase shift of the illumination radiation with respect to the ambient atmosphere in which the mask is to be used.

29. A process in accordance with claim 20, wherein the photosensitive substrate S₀ in step (a) is formed by an alumino-boro-germano-silicate glass having a composition comprising, expressed in terms of mole percentage, 1-6% of Al₂O₃, 10-36% of B₂O₃, 2-20% of GeO₂, 40-80% of SiO₂, 2-10% of R₂O, where R is selected from Li, Na and K, and expressed in terms of weight percentage of the glass, 0-5% of F.

30. A process in accordance with claim 29, wherein the photosensitive substrate S₀ in step (a) is formed by an alumino-boro-germano-silicate glass having a composition comprising, expressed in terms of mole percentage, 2-6% of Al₂O₃, 20-30% of B₂O₃, 5-20% of GeO₂, 42-67% of SiO₂, 2-6% of R₂O, where R is selected from Li, Na and K, and expressed in terms of weight percentage of the glass, 0-5% of F.

31. A process in accordance with claim 29, wherein the alumino-boro-germano-silicate glass is further loaded with molecular hydrogen at a level of at least 10¹⁸ molecules/cm³.

32. A photosensitive alumino-boro-germano-silicate glass with a refractive index n₀, which, when exposed to UV radiation less than 280 nm with a fluence of 50 mJ/cm² for 60 minutes, has a differing modulated refractive index n₁, with n₁≠n₀, said glass having a composition comprising, expressed in terms of mole percentage, 2-6% of Al₂O₃, 20-30% of B₂O₃, 5-20% of GeO₂, 42-67% of SiO₂, 2-6% of R₂O, where R is selected from Li, Na and K, and expressed in terms of weight percentage of the glass, 0-5% of F.

33. A photosensitive glass in accordance with claim 32, wherein the alumino-boro-germano-silicate glass has a composition comprising, expressed in terms of mole percentage, 2-6% of Al₂O₃, 23-27% of B₂O₃, 10-18% of GeO₂, 45-65% of SiO₂, 2-5% of R₂O, where R is selected from Li, Na and K, and expressed in terms of weight percentage of the glass, 1-4.5% of F.

34. A photosensitive glass in accordance with claim 32, further comprising loaded molecular H₂ at a level of at least 10¹⁸ molecules/cm³.

35. A mask blank comprising a substrate S₀, wherein:
(I) the substrate S₀ is formed by a UV photosensitive material having a refractive index n₀ at the wavelength of the radiation used in a lithographic process;
(II) upon selective exposure to UV radiation less than 280 nm at an effective fluence for an effective amount of time, an index pattern P₁ transferable to an image-receiving substrate when subjected to illumination radiation in a lithographic process can be formed within the substrate S₀, said index pattern P₁ having a modulated refractive index n₁, with n₁≠n₀; and
(III) n₀ and n₁ remain substantially the same when exposed to the illumination radiation used in the lithographic process.

36. A mask blank in accordance with claim 35 further comprising, above a surface of the substrate S₀, an additional film of material opaque or attenuating to the illumination radiation used in a lithographic process.

37. A mask blank in accordance with claim 36, wherein the additional film is formed by Cr and/or modified Cr.

38. A mask blank in accordance with claim 36, wherein the photosensitive substrate S₀ is formed by an alumino-boro-germano-silicate glass having a composition comprising, expressed in terms of mole percentage, 1-6% of Al₂O₃, 10-36% of B₂O₃, 2-20% of GeO₂, 40-80% of SiO₂, 2-10% of R₂O, where R is selected from Li, Na and K, and expressed in terms of weight percentage of the glass, 0-5% of F.

39. A mask blank in accordance with claim 38, wherein the photosensitive substrate S₀ is formed by an alumino-boro-germano-silicate glass having a composition comprising, expressed in terms of mole percentage, 2-6% of Al₂O₃, 20-30% of B₂O₃, 5-20% of GeO₂, 42-67% of SiO₂, 2-6% of R₂O, where R is selected from Li, Na and K, and expressed in terms of weight percentage of the glass, 0-5% of F.

40. A mask blank in accordance with claim 38, wherein the alumino-boro-germano-silicate glass is further loaded with molecular hydrogen at a level of at least 10¹⁸ molecules/cm³.
